(19) United States
(12) Patent Application Publication
(10) Pub. No.: US 2025/0365906 A1
(43) Pub. Date: Nov. 27, 2025

(54) DISPLAY ASSEMBLIES WITH VENTS

(71) Applicant: Manufacturing Resources International, Inc., Alpharetta, GA (US)

(72) Inventor: Mike Brown, Cumming, GA (US)

(21) Appl. No.: 19/293,818

(22) Filed: Aug. 7, 2025

Related U.S. Application Data
(63) Continuation of application No. 17/872,441, filed on Jul. 25, 2022, now Pat. No. 12,408,312.
(60) Provisional application No. 63/226,314, filed on Jul. 28, 2021.

(51) Int. Cl. H05K 7/20; G06F 1/20; H05K 5/02

(52) U.S. Cl. CPC H05K 7/20972; H05K 5/0214; H05K 7/20145; G06F 1/203

(57) ABSTRACT

An electronic display assembly with ventilation, and systems and methods related to the same are disclosed. The electronic display assembly includes an electronic display layer located rearward of a cover layer, a closed loop airflow pathway extending within the electronic display assembly, one or more fans located within the closed loop airflow pathway for moving circulating gas within the closed loop airflow pathway when activated, and one or more vents fluidly interposed between the closed loop airflow pathway and an ambient environment.

### CROSS-REFERENCE TO RELATED APPLICATIONS

This application is a continuation of U.S. non-provisional application Ser. No. 17/872,441 filed Jul. 25, 2022, which claims the benefit of U.S. provisional patent application No. 63/226,314 filed Jul. 28, 2021, the disclosures of each of which are hereby incorporated by reference as if fully restated herein.

### TECHNICAL FIELD

Exemplary embodiments relate generally to display assemblies with vents, such as for humidity and/or pressure control.

### BACKGROUND AND SUMMARY OF THE INVENTION

The use of electronic displays, such as for advertising, in the out-of-home market has increased in popularity over recent years. Being located outdoors, such electronic displays are frequently exposed to harsh conditions, including, but not limited to, solar loading, extreme temperatures, precipitation, moisture, contaminants, vandalism, wildlife, and the like. To protect the electronic displays, and associated sensitive components, from such harsh conditions, it is known to place the electronic displays in ruggedized housings. Such housings may fully or partially seal the electronic displays and other associated sensitive components.

It is known to thermally manage such electronic display assemblies using ambient air and/or circulating gas. Such ambient air may pass through one or more open loop airflow pathways within the assembly, and may thermally interact with circulating gas in one or more closed loop airflow pathways within the assembly where such closed loop pathways are used to remove heat generated by the electronic display assemblies, such as at the backlight.

Such electronic display assemblies, particularly those which incorporate fully or partially sealed areas, sometimes experience moisture, such as in the form of humidity, within the interiors of such units, even within the fully or partially sealed area(s), as such area(s) are generally not 100% sealed in a gas impermeable manner. For example, such areas may be partially or fully sealed against contaminants above a given size (e.g., dust or other particulate) and/or liquids, or in accordance with various standards such as IP65, but may still permit at least some gaseous transfer. Such gaseous transfer may bring moisture with it, such as in the form of humidity, potentially resulting in the formation of condensation on interior surfaces of the assemblies. This may result in undesirable fogging or obfuscation of the displayed images, or water damage to sensitive electronic equipment to name some examples.

Additionally, it may be desirable to control air pressure within such electronic display assemblies for various reasons. This may include controlling bowing of electronic displays, wear and tear on seals, or forces experienced on other various sensitive items within the electronic display assemblies. For example, as electronic displays are increasing in size, the large display layers may be subject to bowing or other distortion based on air pressures encountered. In the case of liquid crystal displays, negative pressure on either side of the layer of liquid crystals may result in cell breach and/or color distortion, such as brown mura. As another example, repeated positive and negative net pressure on gaskets or other seals may result in damage overtime. Therefore, what is needed is a system and method for providing selective venting of an electronic display assembly, such as for humidity and/or pressure control.

Systems and methods are disclosed herein which provide selective venting within an electronic display assembly, such as for humidity and/or pressure control. The electronic display assemblies may include one or more vents. Such vents may be installed within the assemblies in a manner which connects the vents between certain fully or partially sealed areas (hereinafter also the “closed loop areas”) and an ambient environment. The vents may be configured to permit circulating gas within the closed loop areas with which the respective vent is connected to only enter, or only exit, the closed loop areas. This may be by design, or may be selectively controlled to operate in such a manner. In particular, as electronic display assemblies become better sealed, the need for ventilation may be required to prevent large pressure fluctuations or levels which may otherwise cause mechanical damage.

The vents may be positioned relative to one or more fan assemblies or other airflow features such that they are located within one or more areas normally experiencing net positive, or relatively high, air pressure of circulating gas within such closed loop areas, or within one or more areas normally experiencing net negative, or relatively low, air pressure of the circulating gas. In exemplary embodiments, the vents are placed within such high/positive air pressure areas and may be configured to vent circulating gas within the closed loop areas to the ambient environment, such as when experiencing certain net positive pressures and/or pressures above a certain threshold. In this manner, humidity or other moisture within the assemblies may be vented with the expelled circulating gas to reduce or eliminate such humidity or other moisture within the assemblies. Alternatively, or additionally, the vents placed within such low/negative air pressure areas may be configured to vent ambient air 32 from the ambient environment into the closed loop areas, such as when experiencing certain net negative pressures and/or pressures below a certain threshold. In this manner, air pressure within the closed loop areas may be raised to, or maintained at, net positive pressure and/or above a certain threshold or relative to other portions of the unit, such as to keep the electronic display layer in compression, to keep humidity and/or other particulate out of the closed loop areas, combinations thereof, or the like. Particularly in the case of liquid crystal displays, compression on the electronic display layer may help to prevent cell breach, brown mura, or other visual distortions. As another example, without limitation, such positive or higher pressures may assist with improving optical performance, such as by preventing distortion by bowing, for example without limitation, of any type or kind of electronic display layer. As yet another example, such positive or higher pressures may assist with driving humidity and other contaminates out of the units.

Opening and closing of the vents may be provided automatically by design of the vents, such as but not limited to, by way of one or more mechanical features of the vents which are designed to operated when experiencing particular absolute or relative pressures. Alternatively, or additionally, opening and closing of the vents may be controlled electronically by one or more controllers. Such opening and closing, by design or electronic operation, may be performed in response to various operating conditions, such as but not limited to, measurements from one or more humidity sensors, temperature sensors, pressure sensors, fan speed sensors, relative pressures experienced at the vents, absolute pressures experienced at the vents, combinations thereof, or the like. In this manner, the vents may be designed and/or controlled to reduce or eliminate condensation, control humidity, and/or maintain positive air pressure within the closed loop areas.

Alternatively, or additionally, the vents may be configured to naturally permit a certain amount of flow from a relatively high-pressure area to a relatively low-pressure area. For example, without limitation, the vents may comprise one or more openings and/or fluid passageways configured to permit various volumetric flow rates at various relative pressures.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical or equivalent features, and wherein:

FIG. 1 is a perspective view of an exemplary electronic display assembly in accordance with the present invention also illustrating section line A-A;

FIG. 2 is a simplified sectional view of an exemplary embodiment of the electronic display assembly of FIG. 1 taken along section line A-A;

FIG. 3 is a simplified sectional view of another exemplary embodiment of the electronic display assembly of FIG. 1 taken along section line A-A;

FIG. 4 is a simplified sectional view of another exemplary embodiment of the electronic display assembly of FIG. 1 taken along section line A-A;

FIG. 5 is a simplified electrical schematic for use with the electronic display assembly of FIG. 1;

FIG. 6 is a flow chart with exemplary logic for operating the electronic display assembly of FIG. 5;

FIG. 7 is a flow chart with other exemplary logic for operating the electronic display assembly of FIG. 5; and

FIG. 8 is a flow chart with other exemplary logic for operating the electronic display assembly of FIG. 5.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

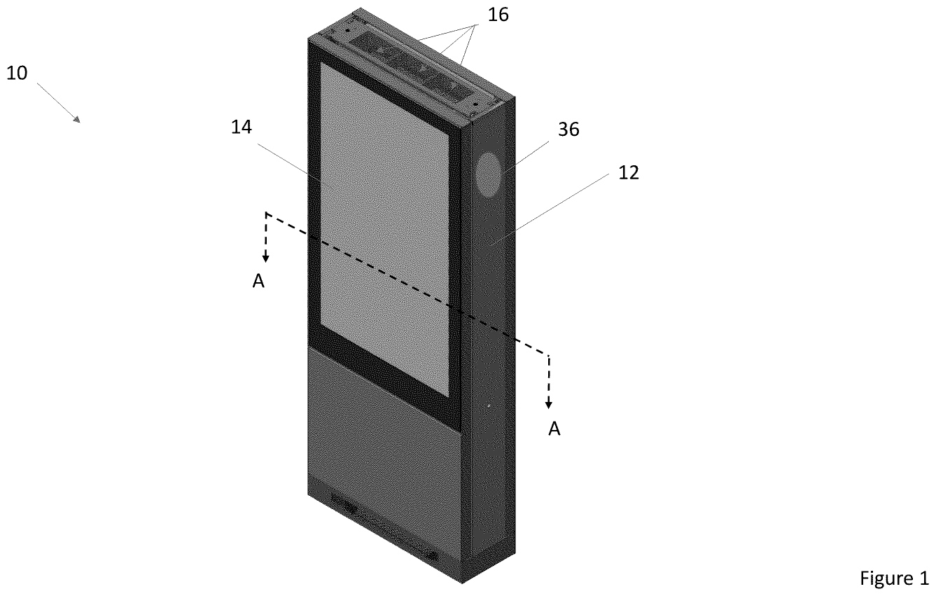

FIG. 1 is a perspective view of an exemplary electronic display assembly (hereinafter also a “unit”) 10 in accordance with the present invention. The unit 10 may include a structural framework 12. The structural framework 12 may be configured for mounting to a ground surface, such as a sidewalk or street, mounting to a wall or other surface, incorporation into street furniture (e.g., phone booths, bus shelters, benches, railings, combinations thereof, or the like), combinations thereof, or the like. The structural framework 12 may comprise one or more members, panels, cladding, combinations thereof, or the like and may be configured to form a complete or partial housing. The structural framework 12 may form a full or partial housing for some or all components of the assembly 10.

The units 10 may comprise one or more electronic display subassemblies 14. Some or all of the electronic display subassemblies 14 may be attached to the structural framework 12 in a moveable manner, though such is not required. For example, the electronic display subassemblies 14 may be attached to the structural framework 12 in a hinged manner to permit selective movement between a closed position whereby certain parts of the units 10 are fully or partially sealed, and an open position whereby certain parts of the interior of the unit 10 are exposed for access. Full or partial sealing may be provided in accordance with one or more standards, such as but not limited to, ingress protection (IP) ratings provided by the International Electrotechnical Commission (e.g., available at https://www.iec.ch/ip-ratings), such as but not limited to, IP 63, 64, 65, 66, 67, and/or 68 by way of non-limiting example.

One or more intakes and exhausts 16 may be provided at the units 10 for ingesting and exhausting ambient air 32.

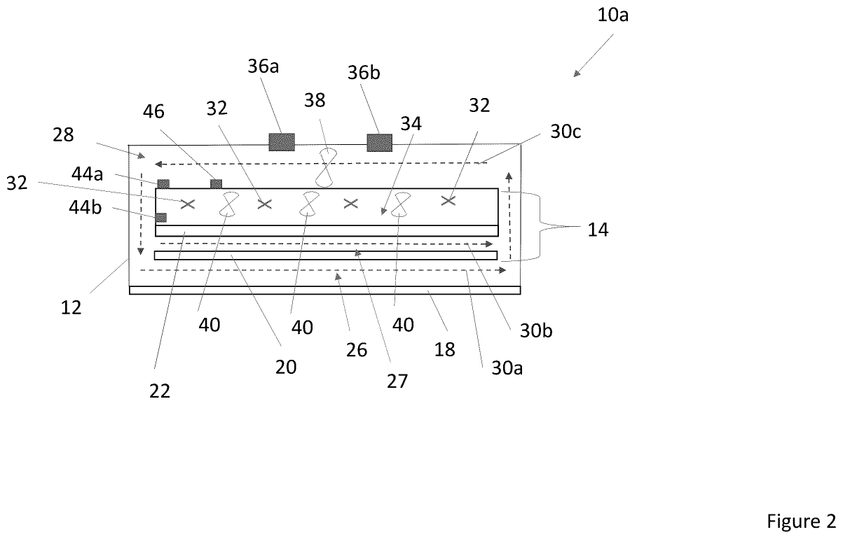

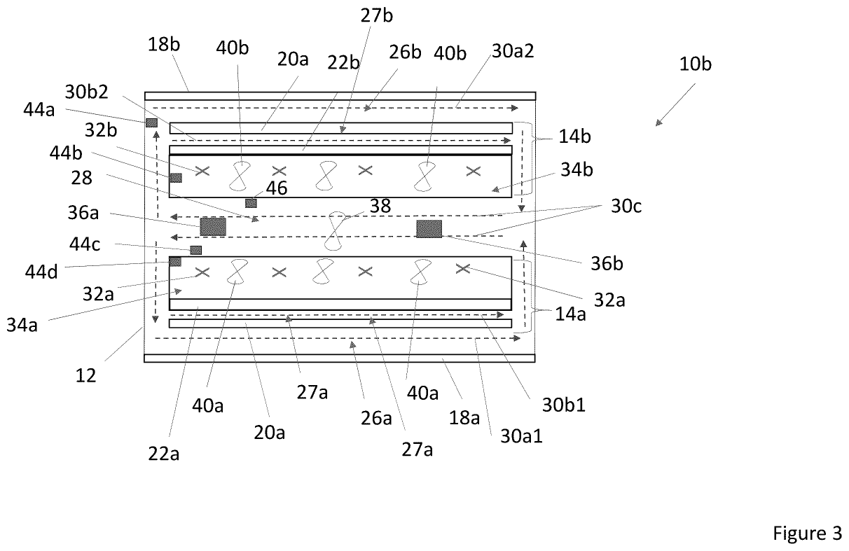

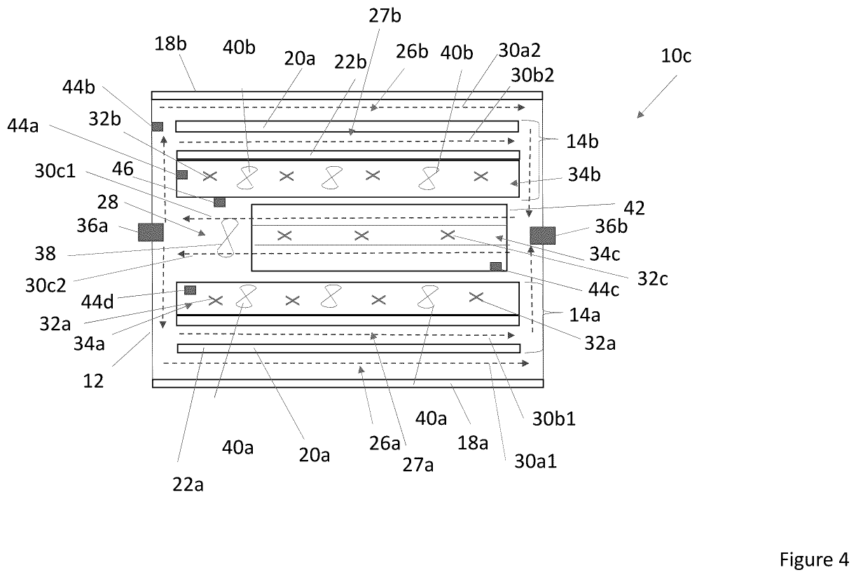

FIG. 2 through FIG. 4 illustrate various exemplary embodiments of airflow pathways within the units 10. FIG. 2 illustrates an exemplary unit 10a with a single electronic display subassembly 14. FIGS. 3 and 4 illustrate exemplary units 10b, 10c with two electronic display subassemblies 14a, 14b placed in a back-to-back arrangement. Any number of electronic display subassemblies 14 may be utilized in any arrangement with the structural framework 12. Similar or the same components used in conjunction with units 10 having multiple electronic display subassemblies 14 may use the same numbering with the addition of an “a”, “b”, “c”, and/or “1”, “2”, etc. (e.g., 14 to 14a, 14b, 30a to 30a1, 30a2).

Each electronic display subassembly 14 may comprise an electronic display layer 20. In exemplary embodiments, the electronic display layer 20 of each of the electronic display subassemblies 14 may comprise an LCD type display with a layer of liquid crystals, and each of the illumination devices 22 may comprise a direct backlight or edge lighting. However, other types of electronic display technologies may be utilized for such electronic display subassemblies 14 including, but not limited to, plasma displays, LED displays, OLED displays, rear projection, cathode ray tube, combinations thereof, or the like.

Each electronic display subassembly 14 may comprise an illumination device 22. In exemplary embodiments, the illumination device 22 may comprise a number of lighting elements, such as LEDs, provided at a substrate. In exemplary embodiments, the illumination device 22 may be provided rearward of the electronic display layer 20 to serve as a direct backlight. In other exemplary embodiments, the illumination device 22 may comprise one or more diffusive and/or transmissive layers and the substrate and/or lighting elements may be positioned about the edge of the electronic display layer 20 to provide edge lighting to the same. In certain exemplary embodiments, such as where the electronic display layer 20 is an LED, OLED, or other type of self-illuminating display, the illumination device 22 may not be required.

The electronic display layer 20 and/or illumination device 22 may be positioned rearward of a cover 18. The cover 18 may comprise one or more layers of a transparent or translucent material. In exemplary embodiments, each cover 18 may comprise two layers bonded with an optically clear adhesive. One or more polarizers, anti-reflective materials, combinations thereof, or the like may be disposed on some or all of the cover 18. The cover 18 may form part of the electronic display subassembly 14 or may be separate therefrom. The cover 18 and the structural framework 12 may together substantially enclose the units 10, such as with intakes/exhausts 16 exempted. The cover 18 may be configured to move with the electronic display subassembly 14, may be configured for independent movement, and/or may be fixed to the structural framework 12.

A single or multiple such electronic display subassemblies 14 may be provided at a single unit 10, such as but not limited to, in a back-to-back arrangement. The electronic display subassemblies 14 may be of the same or different type and may comprise the same or different components. The electronic display subassemblies 14 may be provided in any arrangement such as portrait or landscape.

The intakes and/or exhausts 16 may be fluidly connected to one or more open loop airflow pathways 34 within the units 10. A respective one of the open loop airflow pathways 34a, 34b may extend through a respective one of the electronic display subassemblies 14a, 14b in exemplary embodiments such that an open loop airflow pathway 34 is provided for each one of the electronic display subassemblies 14, which may be entirely separate or separated for a distance and rejoined. For example, without limitation, the open loop airflow pathways 34 may extend behind and along at least a portion of the illumination devices 22 for the electronic display layers 20 and/or behind and along at least a portion of the electronic display layers 20 itself, such as in the case of LED, OLED, or other self-illuminating display. The open loop airflow pathways 34 may comprise one or more corrugated layers in exemplary embodiments. However, any type, arrangement, and/or number of airflow pathway(s) may be utilized. One or more filters may be provided at the intakes and/or exhausts 16 and/or along the one or more open loop airflow pathways 34 within the units 10, though such is not necessarily required.

One or more closed loop airflow pathways may be provided within the units 10. In exemplary embodiments, such closed loop airflow pathways may comprise at least a front chamber 26, which may extend between the cover 18 and the electronic display layer 20, and a rear chamber 28, which may extend behind the electronic display subassembly 14, or at least the electronic display layer 20, but within the structural framework 12. Where multiple electronic display subassemblies 14a, 14b are utilized, the rear chamber 28 may be common to each of the electronic display subassemblies 14a, 14b. A heat exchanger 42 may be located within the rear chamber 28, though such is not required. The heat exchanger 42 may comprise a multilayer heat exchanger configured to accommodate a common flow 30c of the circulating gas through at least some of the layers as well as one or more flows 32c of ambient air through at least some other ones of the layers 34c. However, any type, arrangement, and/or number of airflow pathway(s) may be utilized. One or more filters may be provided at or along the one or more closed loop airflow pathways within the units 10, though such is not necessarily required. Filters, barriers, walls, gaskets, combinations thereof, or the like may provide separation between open and closed loop airflow pathways.

An illumination device chamber 27 may extend between each of the electronic display layers 20a, 20b and the respective illumination devices 22a, 22b. A flow of circulating gas 30c within the rear chamber 28 may be separated such that a first portion 30a flows through the front chamber 26 and a second portion 30b flows through the illumination device chamber 27. The flows 30a, 30b may be recombined, such as in the rear chamber 28.

One or more open loop fans 40 may be provided. The same of different open loop fans 40 may be associated with each of the open loop airflow pathways 34. The open loop fans 40 may be configured to ingest ambient air 32 into the units 10, exhaust ambient air 32 from the assembly 10, and/or move ingested ambient air 32 through the one or more open loop airflow pathways 34 when activated. One or more closed loop fans 38 may be provided. The same or different closed loop fans 38 may be associated with each of the closed loop airflow pathways. The closed loop fans 20 may be configured to move circulating gas through said one or more closed loop airflow pathways when activated. The fans 38, 40 may comprise axial fans, centrifugal fans, combinations thereof, or the like. Any number or type of fans 38, 40 may be used at any location in the units 10, and may be provided in banks or sets. The open loop airflow pathways 34 may be separate from the closed loop airflow pathways, though a complete (e.g., gas impermeable) separation is not necessarily required.

Examples of such airflow configurations and/or operations may include, for example without limitation, those shown and/or described in one or more of U.S. Pat. No. 8,854,595 issued Oct. 7, 2014, U.S. Pat. No. 8,767,165 issued Jul. 1, 2014, U.S. Pat. No. 8,654,302 issued Feb. 18, 2014, U.S. Pat. No. 8,351,014 issued Jan. 8, 2013, U.S. Pat. No. 10,660,245 issued May 19, 2020, U.S. Pat. No. 10,194,564 issued Jan. 29, 2019, and/or U.S. Pat. No. 10,398,066 issued Aug. 27, 2019, the disclosures of each of which are hereby incorporated by reference in their entireties. The structure and/or mechanical operation of the units 10, and the various components thereof, and/or airflow configurations may include those shown and/or described in U.S. Pat. No. 10,485,113 issued Nov. 19, 2019 (the “'133 Patent”), the disclosures of which are hereby incorporated by reference in their entirety. Movement and/or structure for facilitating movement of the electronic display subassemblies 14 may be as shown and/or described in at least the '133 Patent.

The unit 10 may comprise one or more controllers 46. The controller(s) 46 may comprise one or more programmable logic devices. The unit 10 may comprise one or more sensors 44. The sensors 44 may comprise, for example without limitation, temperature sensors, fan speed sensors, airflow sensors, humidity sensors, relatively humidity sensors, air pressure sensors, differential pressure sensors, location sensors, moisture sensors, combinations thereof, or the like. Any type, kind, or number of sensors 44 may be utilized at any number of locations within the units 10. The sensor(s) 44 may be in electronic communication with the controller(s) 46.

Each of the units 10 may comprise one or more vents 36. The vents 36 may be configured for one way operation, such as but not limited to, to only permit circulating gas to vent from a fluidly connected area of the closed loop airflow pathway(s) to the ambient environment, or only permit ambient air 32 from the ambient environment to vent into the fluidly connected area of the closed loop airflow pathway(s). However, two-way vents (ingestion and exhaustion) may alternatively, or additionally, be utilized. Opening and closing of the vents 36 may be configured to occur under certain conditions, such as but not limited to, at certain air pressures, by design and/or may be electronically controlled. For example, without limitation, the vents 36 may be configured to automatically open or close to permit ingestion of ambient air into the closed loop areas and/or exhaustion of circulating gas from the closed loop areas mechanically when experiencing certain conditions, such as but not limited to, certain relative pressure differences between ambient air and circulating gas and/or certain absolute pressures of ambient air and/or circulating gas, based on physical design and/or structure of the vent 36. Alternatively, or additionally, the vents 36 may be configured to be operated mechanically based on electronic command, such as but not limited to, by one or more motors.

In exemplary embodiments, each of the vents 36 may be connected to one or more areas of one or more closed loop airflow pathway(s) within the unit 10, and the ambient environment directly or to one of more of the open loop airflow pathways 34. Such connections may be direct, such as where the vent 36 extends between such environments, or indirect, such as by way of tubing or other fluid passageways. The vents 36 may connect to the ambient environment directly and/or by way of the one or more of the open loop airflow pathways 34.

Some or all of the vents 36 may be passive vents. The vents 36 may be configured to naturally permit flow of air from relatively high-pressure areas to relatively low-pressure areas. Some or all of the vents 36 may comprise fluid passageways such that the vents 36 are capable of selectively releasing circulating gas and/or ingesting ambient air. The size and/or shape of openings in and/or fluid passageways within the vents 36 may be configured to permit various volumetric flow rates at various relative pressures. The size and/or shape of openings in and/or fluid passageways within the vents 36 may be configured to naturally resist particulate and/or water ingestion. The vents 36 may optionally include one or more filters, membranes, or the like configured to resist or prevent particulate and/or water ingestion and/or permit one way flow of air.

Examples of such vents include, for example without limitation, those available from W. L. Gore & Associates, Inc. of Newark, DE (https://www.gore.com/products/categories/venting) and/or Amphenol Corp., of Wallingford, Ct. (https://www.amphenol.com/), including but not limited to the VEN-PS1NBK-08001 and/or VEN-PS1NBK-08002 products from Amphenol. These are merely exemplary and are not intended to be limiting.

In exemplary embodiments, a first one of the vents 36a may be placed on a first side of one of the closed loop fans 38 which may be associated with relatively high and/or net positive pressures when the fan 38 is operated. A second one of the vents 36b may be placed on a second side of one of the same or different ones of the closed loop fans 38, such as associated with relatively low and/or net negative pressures when the fan 38 is operated. In other exemplary embodiments, a single or multiple vents 36 may be placed exclusively on one side of the closed loop fans 38. Any number of vents 36 in any number of locations may be utilized. The vents 36 may be configured to ingest ambient air into, and/or exhaust circulating gas from, the associated closed loop areas. In exemplary embodiments, without limitation, one or more passive type vents 63 is placed in close proximity to a negative pressure side of the closed loop fans 38. In other exemplary embodiments, without limitation, one or more passive type vents 36 is placed in close proximity to a positive pressure side of the closed loop fans 38.

In exemplary embodiments, one or more of the vents 36 may be positioned on a side of the closed loop fans 38 associated with negative, or relatively low pressure primarily for ingesting ambient air into the associated closed loop area. In this manner, pressures within the closed loop airflow pathways, including the portions of the flow 30a and 30b within the front chamber 26 and the illumination devices chamber 27 may be raised to, and/or maintained at, positive pressures to place or keep the electronic display layer 20 in compression. This may prevent cell breach and/or color distortion.

Alternatively, or additionally, one or more of the vents 36 may be positioned on a side of the closed loop fans 38 associated with positive, or relatively high pressure primarily for exhausting circulating gas in the associated closed loop area to the ambient environment. In this manner, circulating gas may be periodically driven out of the closed loop areas. This may reduce or eliminate moisture and other contaminants. This may also maintain the electronic display layer 20 in tension, such as to keep it taught.

In exemplary embodiments, placement of, or at least selective opening of, one or more vents 36 on the side of the closed loop fans 38 associated with relatively high and/or net positive pressures when the fan 38 is operated may result in increasing the average pressure of the circulating gas in the associated closed loop area as compared to without such one or more vents 36 and/or keeping such one or more vents 36 closed. In exemplary embodiments, placement of, or at least selective opening of, one or more vents 36 on the side of the closed loop fans 38 associated with negative, or relatively low pressure when the fan 38 is operated may result in decreasing the average pressure of the circulating gas in the associated closed loop area as compared to without such one or more vents 36 and/or keeping such one or more vents 36 closed. In this manner, placement and/or operation of the vent(s) 36 may be controlled to control or influence pressures of circulating gas in the closed loop airflow pathway.

Alternatively, or additionally, the vent(s) 36 may be fluidly connected to such areas (e.g., those on the positive of negative side of the closed loop fans 38). Such fluid connection may be made by way of tubes, for example without limitation. This may permit the vent(s) 36 to be placed in more convenient locations and fluidly connected to the desired region, such as to accomplish the same, or substantially the same, effect while permitting greater design variation and/or where desired placement is impractical or impossible.

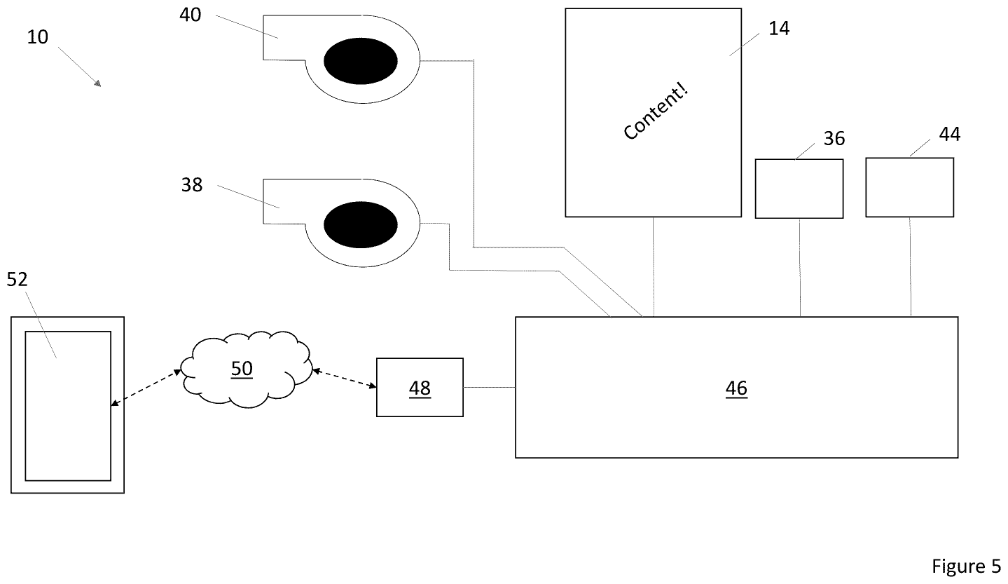

FIG. 5 is a simplified electrical schematic for use with the electronic display assembly 10. The controller 46 may be in electronic communication with some or all components of the assembly 10. The controller 46 may be in electronic communication with each of the electronic display subassemblies 14. The controller 46 may be in electronic communication with each of the closed loop fans 38. The controller 46 may be in electronic communication with each of the open loop fans 40. The controller 46 may be in electronic communication with each of the sensors 44. The controller 46 may be in electronic communication with each of the vents 36. The controller 46 may be configured to receive data from such components and/or send commands to such components by wired or wireless connection. For example, without limitation, the controller 46 may be configured to open or close the vents 36, control speeds of the fans 38, 40, content displayed at the electronic display subassemblies 14, take measurements from the sensors 44, combinations thereof, or the like. Such electronic communication is not required between the controller 46 and the aforementioned components. For example, without limitation, the vents 36 may be configured to operate based on experienced conditions (e.g., pressures) and without the need for electronic control.

The controller 46 may be in electronic communication with a network communication device 48. The network communication device 48 may be configured to receive data from the controller 46 for transmission over one or more networks 50 to one or more electronic devices 52, such as to permit remote monitoring of the units 10. The network communication device 48 may be configured to receive commands from the one or more electronic devices 52 for passing to the controller 46, such as to permit remote control over the units 10. The networks 50 may comprise cellular networks, wireless networks, wired networks, combinations thereof, or the like. The electronic devices 52 may comprise personal computers, smartphones, tablets, network operation centers, combinations thereof, or the like.

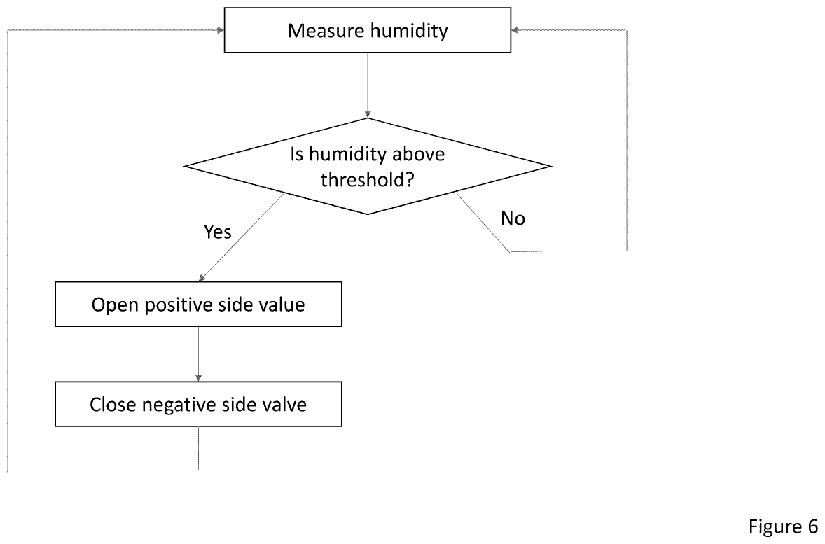

FIG. 6 is a flow chart with exemplary logic for operating the electronic display assembly 10. Humidity may be measured by way of at least one of the sensors 44, which may comprise a humidity sensor and/or relative humidity sensor (e.g., psychrometer). The measurement(s) may be reported to, or determined at, the controller 46 from data received from the at least one of the sensors 44. If the humidity is above a threshold, the controller 46 may be configured to open at least one of the vents 36. In exemplary embodiments, the controller 46 may be configured to open one or more of the vents 36 on a positive or relatively high-pressure side of one or more of the closed loop fans 38. The controller 46 may, alternatively or additionally, be configured to close one or more of the vents 36 on a negative or relatively low-pressure side of one or more of the closed loop fans 38. In other exemplary embodiments, the controller may be configured to open one or more of the vents 36 configured for one-way expulsion of circulating gas and/or close one or more of the vents configured for one-way ingestion of ambient air. Such operations may occur simultaneously or in sequence. This may permit expulsion of moisture from the units 10 with the expelled circulating gas. The threshold may be any amount. In exemplary embodiments, the threshold is set to reflect a point in which condensation is likely to form within the unit 10, with or without a margin of safety.

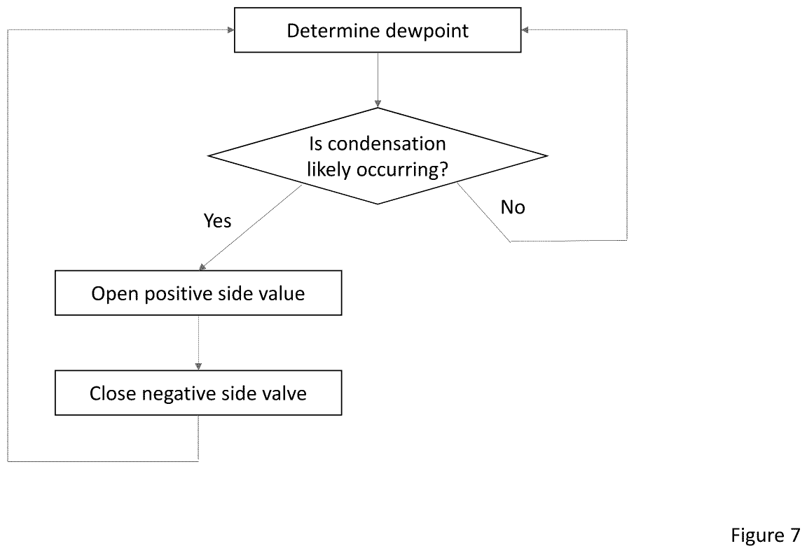

FIG. 7 is a flow chart with other exemplary logic for operating the electronic display assembly 10. Relative humidity may be measured by way of at least one of the sensors 44. Air temperature may be measured by way of the same or different one(s) of the sensors 44. These measurements may be reported to, or determined at, the controller 46 from data received from the sensor(s) 44. Alternatively, or additionally, such measurements may be taken from one or more internet-based sources, such as by way of the network communication device 48. The controller 46 may be configured to determine a dewpoint for the measured air, which may be air within the units 10 or ambient, and calculate a dewpoint spread relative to the air temperature measurements, which may be ambient air within the units 10 or ambient air outside the units 10. In exemplary embodiments, dewpoint is calculated for circulating gas within the unit 10 and dewpoint spread is measured relative to ambient air outside of, or within, the units 10.

Where dewpoint spread reaches one or more thresholds, such as but not limited to within 5° C., the controller 46 may be configured to open one or more of the vents 36 on a positive or relatively high-pressure side of one or more of the closed loop fans 38. The controller 46 may, alternatively or additionally, be configured to close one or more of the vents 36 on a negative or relatively low-pressure side of one or more of the closed loop fans 38. Alternatively, or additionally, the controller 46 may be configured to operate such vents 36 in a manner which only permits circulating gas to be expelled from the unit 10 to ambient. Such operations may occur simultaneously or in sequence. In this manner, moisture may be expelled from the units 10 with the expelled circulating gas. The dewpoint spread threshold may be any amount.

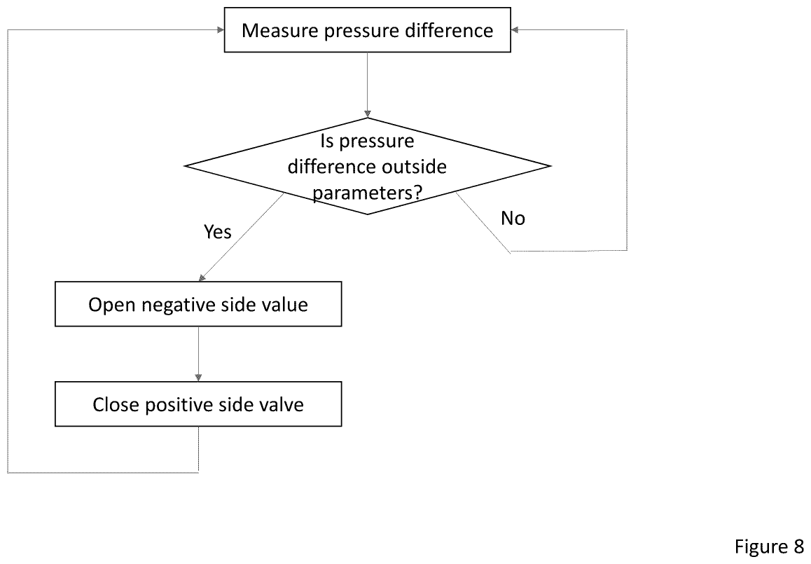

FIG. 8 is a flow chart with other exemplary logic for operating the electronic display assembly 10. Air pressure readings of circulating gas, such as but not limited to, the portion 30a of circulating gas within the front chamber 26 and/or the portion 30b of the circulating gas within the illumination devices chamber 27 may be measured by way of one or more of the sensors 44. The measurements may be reported to, or determined at, the controller 46 from data received from the sensors 44. The controller 46 may be configured to determine if the pressures differential between the first and second portions 30a, 30b is within certain operating conditions. Such operating conditions may be, for example without limitation, both positive. Alternatively, or additionally, such operating conditions may be, without limitation, higher within the front chamber 26 relative within the illumination device chamber 27. These operating conditions may be configured to reduce or eliminate bowing of the electronic display layer 20, and/or maintain compressive forces on the electronic display layer 20. Where such pressure falls outside of desired conditions, the vents 36 may be selectively operated to control the same. For example, without limitation, one or more of the vents 36 associated with negative or relatively low pressure may be opened and/or configured for ingestion of ambient air so as to raise pressures within the closed loop airflow pathway.

While electronic control of the vents 36 is contemplated in at least certain embodiments, such as but not limited to, those shown and/or described with regard to FIGS. 5-8, the vents 36 may be configured to automatically operate by mechanical design in response to various conditions, such as pressures or relative pressures, experienced and thus such electronic control may not be required. The vents 36 may be configured, for example without limitation, to automatically operate mechanically by engineered deign and without physical control, in response to the conditions shown and/or described herein and/or achieve the results (e.g., humidity reduction, pressure miniatous) shown and/or described herein.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention. It is the intention, therefore, to limit the invention only as indicated by the scope of the claims.

Certain operations described herein may be performed by one or more electronic devices. Each electronic device may comprise one or more processors, electronic storage devices, executable software instructions, and the like configured to perform the operations described herein. The electronic devices may be general purpose computers or specialized computing device. The electronic devices may comprise personal computers, smartphone, tablets, databases, servers, or the like. The electronic connections and transmissions described herein may be accomplished by wired or wireless means. The computerized hardware, software, components, systems, steps, methods, and/or processes described herein may serve to improve the speed of the computerized hardware, software, systems, steps, methods, and/or processes described herein.

What is claimed is:

1. An electronic display assembly with ventilation, said electronic display assembly comprising:
a cover layer;
an electronic display layer located rearward of the cover layer;
a closed loop airflow pathway extending within the electronic display assembly;
one or more fans located within the closed loop airflow pathway for moving circulating gas within the closed loop airflow pathway when activated; and
one or more vents fluidly interposed between the closed loop airflow pathway and an ambient environment.

2. The electronic display assembly of claim 1 further comprising:
a structural framework;
an electronic display subassembly comprising the cover layer and the electronic display layer, wherein the electronic display subassembly is attached to said structural framework in a manner which permits movement of said electronic display subassembly relative to the structural framework;
an enclosure for at least the electronic display layer, said enclosure defined, at least in part, by the structural framework and the cover layer; and
wherein the cover layer is transparent or translucent and forms, at least in part, a forward surface of said electronic display subassembly.

3. The electronic display assembly of claim 1 wherein:
said one or more vents are movable between an open state and a closed state.

4. The electronic display assembly of claim 3 further comprising:
a controller in electronic communication with the one or more vents and configured to electronically operate said one or more vents between the open state and the closed state.

5. The electronic display assembly of claim 4 further comprising:
one or more sensors in electronic communication with said controller, wherein said controller is configured to operate said one or more vents between said open state and said closed state, at least in part, based on data received from said one or more sensors.

6. The electronic display assembly of claim 5 wherein:
a first one of the one or more vents is located adjacent to a first side of said one or more fans;
a second one of the one or more vents is located adjacent to a second side of said one or more fans;
said one or more sensors comprise a differential pressure sensor fluidly connected to said closed loop airflow pathway and the ambient environment or multiple pressure sensors, a first of which is fluidly connected to said closed loop airflow pathway and a second of which is fluidly connected to the ambient environment; and
said controller is configured to operate the first one of said vents in said closed state and said second one of said vents in said open state after determining, based on data received from said one or more sensors, that a measured pressure difference between the circulating gas of the closed loop airflow pathway and ambient air of the ambient environment does not meet one or more predetermined parameters.

7. The electronic display assembly of claim 5 wherein:
a first one of the one or more vents is located adjacent to a first side of said one or more fans;
a second one of the one or more vents is located adjacent to a second side of said one or more fans;
said one or more sensors comprise a humidity sensor; and
said controller is configured to operate the first one of said vents in said open state and said second one of said vents in said closed state after determining, based on data received from said humidity sensor, that a measured humidity or dewpoint spread does not meet one or more predetermined parameters.

8. The electronic display assembly of claim 5 wherein:
a first one of the one or more vents is located adjacent to a first side of said one or more fans;
a second one of the one or more vents is located adjacent to a second side of said one or more fans;
said one or more sensors comprise a temperature sensor located at the closed loop airflow pathway; and
said controller is configured to:
measure a temperature of circulating gas within the closed loop airflow pathway by way of the temperature sensor;
determine a dewpoint of ambient air of the ambient environment;
determine a dewpoint spread between the temperature and the dewpoint; and
where the dewpoint spread is below a predetermined threshold:
operate the first one of said vents in said open state; and
operate the second one of said vents in said closed state.

9. The electronic display assembly of claim 1 wherein:
each of the one or more vents comprise two-way vents configured to selectively permit exhaustion of the circulating gas from the closed loop airflow pathway and ingestion of ambient air into the closed loop airflow pathway to become circulating gas.

10. The electronic display assembly of claim 9 wherein:
each of said one or more vents comprise one or more selectively gas permeable membranes configured to resist ingestion of particulate and water.

11. The electronic display assembly of claim 10 wherein:
at least one of said one or more selectively gas permeable membranes comprises polytetrafluoroethylene.

12. The electronic display assembly of claim 9 wherein:
each of said one or more vents permit said ingestion and said exhaustion at certain pressure differential levels between the circulating gas and the ambient air and resist said ingestion and said exhaustion at other pressure differential levels between the circulating gas and the ambient air.

13. The electronic display assembly of claim 12 wherein:
each of said one or more vents are configured to permit said ingestion and said exhaustion at certain volumetric flow rates.

14. The electronic display assembly of claim 1 wherein:
each of the one or more vents comprise one-way vents configured to permit only one of: exhaustion of the circulating gas from the closed loop airflow pathway, and ingestion of ambient air into the closed loop airflow pathway.

15. The electronic display assembly of claim 1 wherein:
each of the said one or more vents are located adjacent to a negative pressure side of the one or more fans.

16. The electronic display assembly of claim 1 wherein:
a first one of the one or more vents is located adjacent to a first side of said one or more fans; and
a second one of the one or more vents is located adjacent to a second side of said one or more fans.

17. The electronic display assembly of claim 1 wherein:
a first portion of said closed loop airflow pathway extends between said cover and said electronic display layer, a second portion of said closed loop airflow pathway extends rearward of said electronic display layer;
said electronic display layer comprises liquid crystals; and
said electronic display assembly comprises a backlight located rearward of the electronic display layer.

18. The electronic display assembly of claim 1 further comprising:
an open loop airflow pathway for ambient air extending within the electronic display assembly, wherein said closed loop airflow pathway is separated from an ambient air in accordance with a standard at least as restrictive as ingress protection code 65.

19. An electronic display assembly with ventilation, said electronic display assembly comprising:
a structural framework;
an electronic display subassembly attached to the structural framework in a moveable fashion and comprising a cover layer, which is transparent or translucent, an electronic display layer comprising liquid crystals located behind the cover layer, and a backlight comprising light emitting diodes located rearward of the electronic display layer;
an enclosure for at least the electronic display layer, said enclosure defined, at least in part, by the structural framework and the cover layer;
a closed loop airflow pathway extending within the enclosure;
an open loop airflow pathway extending within the enclosure;
one or more fans located within the closed loop airflow pathway for moving circulating gas within the closed loop airflow pathway when activated; and
one or more vents fluidly interposed between the closed loop airflow pathway and an ambient environment, wherein each of the one or more vents:
comprise two-way vents configured to selectively permit exhaustion of the circulating gas from the closed loop airflow pathway and ingestion of ambient air into the closed loop airflow pathway to become circulating gas;
comprise one or more membranes configured to resist ingestion of particulate and water;
are configured to permit said ingestion and said exhaustion in response to certain pressure differentials between the circulating gas and the ambient air and resist said ingestion and said exhaustion in response to other pressure differentials between the circulating gas and the ambient air;
are configured to permit said ingestion and said exhaustion at certain volumetric flow rates; and
are located adjacent to a first side of the one or more fans.

20. An electronic display assembly with ventilation, said electronic display assembly comprising:
a structural framework;
electronic display subassemblies, each attached to a respective side of the structural framework in a moveable fashion and comprising a cover layer, which is transparent or translucent, an electronic display layer comprising liquid crystals located behind the cover layer, and a backlight comprising light emitting diodes located rearward of the electronic display layer;
an enclosure for at least the electronic display layer of each of the electronic display subassemblies, said enclosure defined, at least in part, by the structural framework and the cover layer of each of the electronic display subassemblies;
a closed loop airflow pathway extending within the enclosure, and within and between each of the electronic display subassemblies;
one or more open loop airflow pathways extending within the enclosure and each of the electronic display subassemblies;
fans located within the closed loop airflow pathway for moving circulating gas within the closed loop airflow pathway when activated;
fans located within the one or more open loop airflow pathways for moving ambient air within the one or more open loop airflow pathways when activated; and
one or more vents fluidly interposed between the closed loop airflow pathway and an ambient environment, wherein each of the one or more vents:
comprise two-way vents configured to selectively permit exhaustion of the circulating gas from the closed loop airflow pathway and selectively permit ingestion of ambient air into the closed loop airflow pathway to become circulating gas;
comprise one or more membranes configured to resist ingestion of particulate and water;
are configured to permit said ingestion and said exhaustion in response to certain pressure differentials between the circulating gas and the ambient air and resist said ingestion and said exhaustion in response to other pressure differentials between the circulating gas and the ambient air;
are configured to permit said ingestion and said exhaustion at certain volumetric flow rates; and
are located adjacent to a first side of the fans.
